(19) United States
(12) Patent Application Publication
(10) Pub. No.: US 2026/0049644 A1
(43) Pub. Date: Feb. 19, 2026

(54) VIBRATION ABSORBING APPARATUS FOR A SEMICONDUCTOR MANUFACTURING APPARATUS

(71) Applicant: SAMSUNG ELECTRONICS CO., LTD, SUWON-SI (KR)

(72) Inventors: Sangkeun AHN, Suwon-si (KR); Jooyoung YOON, Suwon-si (KR); Ilhyoung KOO, Suwon-si (KR); Sooyeol PARK, Suwon-si (KR); Wanseung KIM, Seoul (KR); Junhong PARK, Seongnam (KR); Kyunglae GU, Seoul (KR); Narae KIM, Seoul (KR); Sunghyun KIM, Daejeon (KR); Huichan JANG, Seoul (KR)

(73) Assignee: Industry-University Cooperation Foundation Hanyang University, Seoul (KR)

(21) Appl. No.: 19/052,928

(22) Filed: Feb. 13, 2025

(30) Foreign Application Priority Data
Aug. 13, 2024 (KR) 10-2024-0108372

(51) Int. Cl. F16F 7/10; H01L 21/67

(52) U.S. Cl. CPC F16F 7/10; H01L 21/67155; F16F 2222/08; F16F 2228/04

(57) ABSTRACT

A vibration absorbing apparatus for semiconductor manufacturing apparatus including: a base plate configured to be secured to a semiconductor manufacturing apparatus; a first vibration absorber including a first elastic body fastened to the base plate and a first mass body fastened to the first elastic body; and a second vibration absorber including a second elastic body fastened to the base plate and a second mass body fastened to the second elastic body, wherein the second elastic body is adjacent to the first elastic body, wherein the first mass body and the second mass body are configured to reduce vibration at specific frequencies transmitted to the base plate by colliding with each other.

### CROSS-REFERENCE TO RELATED APPLICATION

This application claims priority under 35 U.S.C. § 119 to Korean Patent Application No. 10-2024-0108372, filed on Aug. 13, 2024, in the Korean Intellectual Property Office (KIPO), the disclosure of which is incorporated by reference herein in its entirety.

### 1. TECHNICAL FIELD

Example embodiments of the present inventive concept relate to a vibration absorbing apparatus for reducing vibrations in an apparatus. More particularly, the example embodiments relate to a vibration absorbing apparatus including a mass body and an elastic body.

### 2. DESCRIPTION OF THE RELATED ART

Vibration in semiconductor manufacturing apparatuses can reduce process accuracy, such as manufacturing and measurement precision, and may also cause damage to driving components of the apparatus, such as bearings and motors. To mitigate vibrations in semiconductor manufacturing apparatuses, several approaches have been employed, including anti-vibration pads that utilize the energy-attenuation properties of rubber materials, independent foundations (or floor reinforcements) to block the transmission of vibrations, and dynamic absorbers employing mass-spring systems. However, each of these methods has limitations. The vibration-reducing effect of anti-vibration pads may decrease significantly at certain frequencies, especially at low frequencies. Independent foundations or floor reinforcements often require additional construction, which can be expensive and time-consuming. Similarly, dynamic absorbers are typically effective only within specific frequency ranges. In particular, when using dynamic absorbers, their vibration-reducing effectiveness may decrease if the target frequency of the vibrations generated by the semiconductor manufacturing apparatus changes. This effectiveness may also decrease if the set frequency (or natural frequency) of the dynamic absorber changes over time due to prolonged exposure to vibrations.

### SUMMARY

Example embodiments of the present inventive concept provide a vibration absorbing apparatus for semiconductor manufacturing apparatus, the vibration absorbing apparatus configured to effectively reduce vibrations by absorbing them over a relatively wide frequency range.

According to an example embodiment of the present inventive concept, there is provided a vibration absorbing apparatus for semiconductor manufacturing apparatus including: a base plate configured to be secured to a semiconductor manufacturing apparatus; a first vibration absorber including a first elastic body fastened to the base plate and a first mass body fastened to the first elastic body; and a second vibration absorber including a second elastic body fastened to the base plate and a second mass body fastened to the second elastic body, wherein the second elastic body is adjacent to the first elastic body, wherein the first mass body and the second mass body are configured to reduce vibration at specific frequencies transmitted to the base plate by colliding with each other.

According to an example embodiment of the present inventive concept, there is provided a vibration absorbing apparatus for semiconductor manufacturing apparatus including: a base plate configured to be secured to a semiconductor manufacturing apparatus; a first beam structure including a first fixed end portion secured to the base plate and a first free end portion extending from the first fixed end portion; a second beam structure adjacent to the first beam structure and including a second fixed end portion secured to the base plate and a second free end portion extending from the second fixed end portion; a first mass body fastened to the first free end portion of the first beam structure; and a second mass body fastened to the second free end portion of the second beam structure, wherein the first mass body and the second mass body partially overlap each other, and the first mass body and the second mass body are configured to reduce vibrations at frequencies applied to the base plate by colliding with each other.

According to an example embodiment of the present inventive concept, there is provided a vibration absorbing apparatus for semiconductor manufacturing apparatus including: a base plate configured to be secured to a semiconductor manufacturing apparatus, the base plate having a first surface and a second surface facing each other; a first beam structure including a first fixed end portion secured to the first surface of the base plate and a first free end portion extending from the first fixed end portion and having a first slit formed along an extending direction; a second beam structure spaced apart from the first beam structure and including a second fixed end portion secured to the first surface of the base plate and a second free end portion extending from the second fixed end portion and having a second slit formed along the extending direction; a first mass body positioned along the first slit; and a second mass body positioned along the second slit and extending toward the first mass body such that the second mass body is at least partially overlapped with the first mass body, wherein the first mass body and the second mass body are configured to reduce vibrations at certain frequencies applied to the base plate by colliding with each other.

Accordingly, the vibration absorbing apparatus for a semiconductor manufacturing apparatus may absorb vibrations across a relatively wide frequency range. Additionally, the collision between the first mass body and the second mass body dissipates the vibration energy, thereby effectively reducing the vibrations generated by the semiconductor manufacturing apparatus.

Furthermore, the first mass body may be positioned along a first guide provided in the first elastic body, and the second mass body may be positioned along a second guide provided in the second elastic body.

Accordingly, the vibration absorbing apparatus for a semiconductor manufacturing apparatus may easily adjust its set frequency (or natural frequency) to accommodate the vibrations generated by the semiconductor manufacturing apparatus.

### BRIEF DESCRIPTION OF THE DRAWINGS

FIG. 1 is a perspective view illustrating a semiconductor manufacturing apparatus with a vibration absorbing apparatus in accordance with example embodiments of the present inventive concept.

FIG. 2 is a perspective view illustrating the vibration absorbing apparatus in FIG. 1.

FIG. 3 is a plan view illustrating the vibration absorbing apparatus in FIG. 1.

FIG. 4 is a cross-sectional view taken along the line C1-C1′ in FIG. 3.

FIG. 5 is a cross-sectional view taken along the line C2-C2′ in FIG. 3.

FIG. 6 is a cross-sectional view taken along the line C3-C3′ in FIG. 3.

FIG. 7 is a plan view illustrating a vibration absorbing apparatus in accordance with example embodiments of the present inventive concept.

FIG. 8 is a cross-sectional view taken along the line C4-C4′ in FIG. 7.

FIG. 9 is a cross-sectional view taken along the line C5-C5′ in FIG. 7.

FIG. 10 is a plan view illustrating a vibration absorbing apparatus in accordance with example embodiments of the present inventive concept.

FIG. 11 is a cross-sectional view taken along the line C6-C6′ in FIG. 10.

FIG. 12 is a plan view illustrating a vibration absorbing apparatus in accordance with example embodiments of the present inventive concept.

FIG. 13 is a cross-sectional view taken along the line C7-C7′ in FIG. 12.

FIG. 14 is a plan view illustrating a vibration absorbing apparatus in accordance with example embodiments of the present inventive concept.

FIG. 15 is a cross-sectional view taken along the line C8-C8′ in FIG. 14.

FIG. 16 is a plan view illustrating a vibration absorbing apparatus in accordance with example embodiments.

FIG. 17 is a cross-sectional view taken along the line C9-C9′ in FIG. 16.

FIGS. 18, 19, 20, 21 and 22 are views illustrating a method of absorbing vibration in accordance with example embodiments of the present inventive concept.

### DETAILED DESCRIPTION OF EXAMPLE EMBODIMENTS

Hereinafter, example embodiments of the present inventive concept will be explained in detail with reference to the accompanying drawings.

This invention describes a vibration-absorbing apparatus specifically designed for semiconductor manufacturing equipment to improve accuracy and reduce wear and tear caused by vibrations. The system consists of a base plate mounted on the semiconductor apparatus and multiple dynamic vibration absorbers, each comprising an elastic body and a mass body. These mass bodies are uniquely configured to collide with one another, dissipating vibration energy through mechanical impacts, which reduces the transmitted vibrations across a broad frequency range. This design ensures consistent performance, even when vibration frequencies change due to prolonged use or operational variability.

Key innovations include adjustable mass positioning along guides within the elastic bodies, allowing fine-tuning of the system's natural frequencies to match the target frequencies of the equipment. This adaptability enhances vibration reduction and minimizes the need for costly external construction like reinforced foundations. The apparatus also incorporates protective features, such as a cover for shielding from external impacts, and allows integration into existing equipment with minimal structural modification. This approach is a cost-effective, adaptable solution for maintaining precision in semiconductor manufacturing processes.

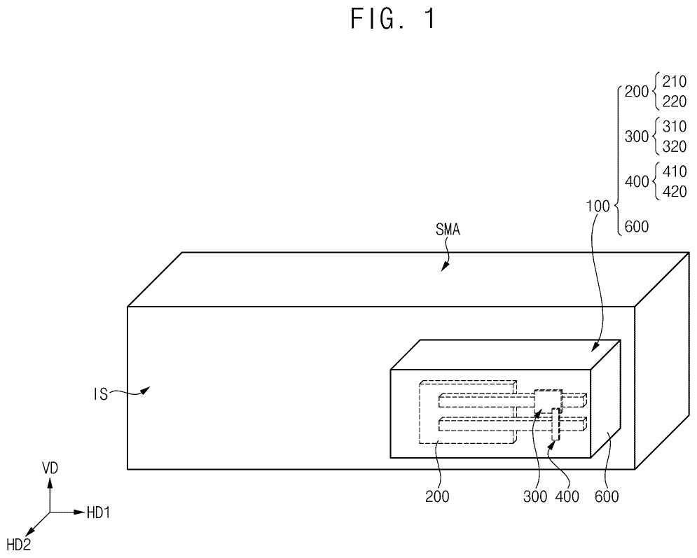

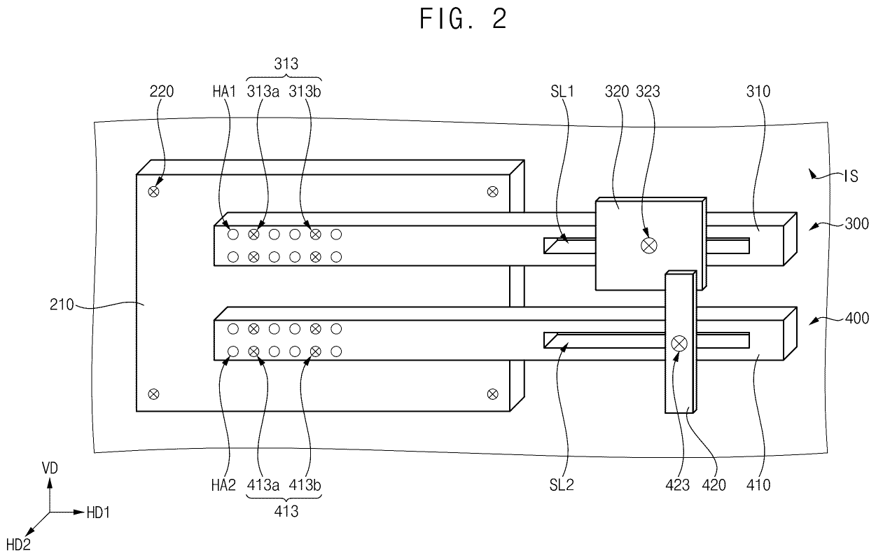

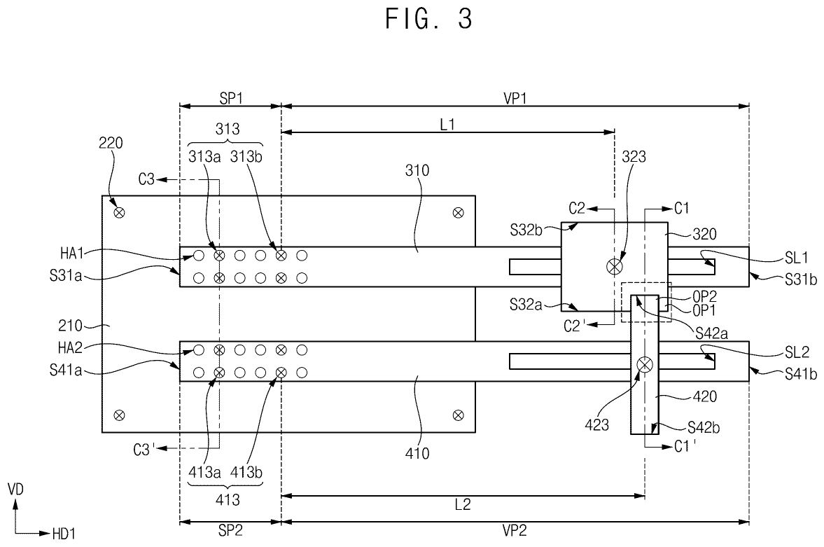

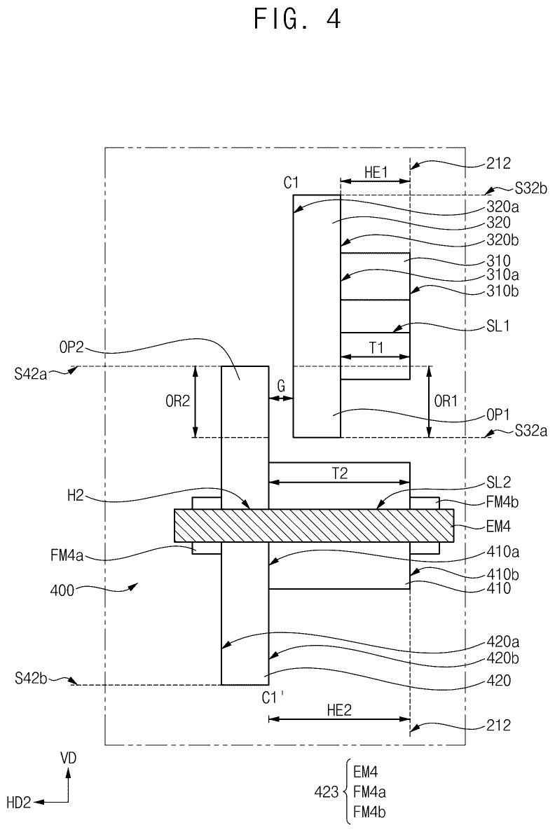

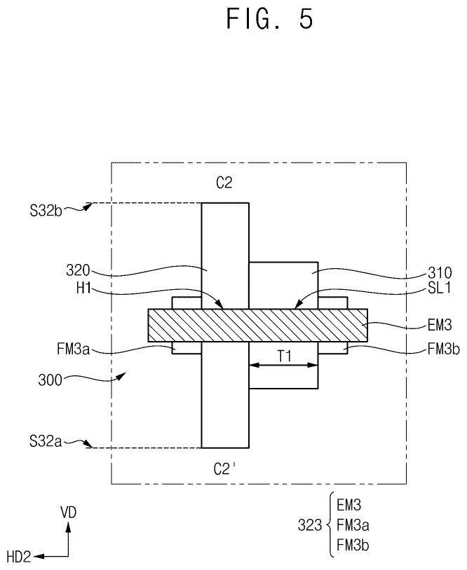

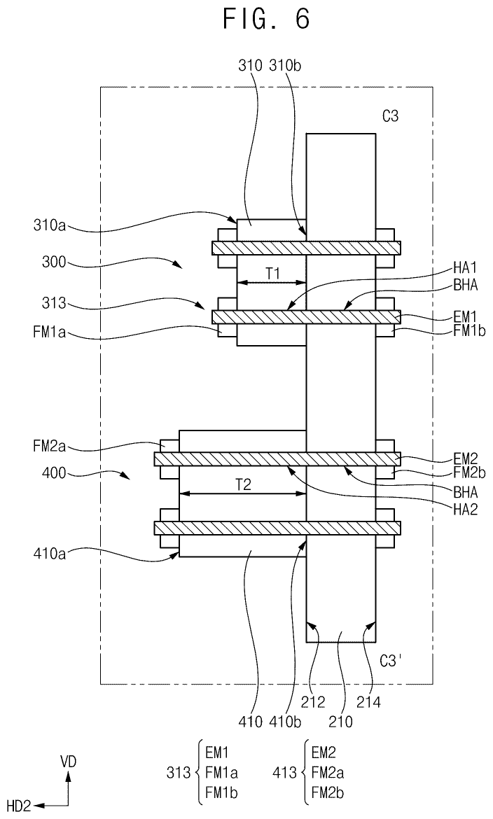

FIG. 1 is a perspective view illustrating a semiconductor manufacturing apparatus with a vibration absorbing apparatus in accordance with example embodiments of the present inventive concept. FIG. 2 is a perspective view illustrating the vibration absorbing apparatus in FIG. 1. FIG. 3 is a plan view illustrating the vibration absorbing apparatus in FIG. 1. FIG. 4 is a cross-sectional view taken along the line C1-C1′ in FIG. 3. FIG. 5 is a cross-sectional view taken along the line C2-C2′ in FIG. 3. FIG. 6 is a cross-sectional view taken along the line C3-C3′ in FIG. 3.

Referring to FIGS. 1 to 6, a vibration absorbing apparatus 100 for a semiconductor manufacturing apparatus may include a base 200 provided on a surface IS of a semiconductor manufacturing apparatus SMA, a first dynamic vibration absorber 300 provided on the base 200, and a second dynamic vibration absorber 400 provided on the base 200 and adjacent to the first dynamic vibration absorber 300. The vibration absorbing apparatus 100 for a semiconductor manufacturing apparatus may further include a cover 600 surrounding the base 200, the first dynamic vibration absorber 300, and the second dynamic vibration absorber 400 to physically protect the base 200, the first dynamic vibration absorber 300, and the second dynamic vibration absorber 400 from external impact.

The vibration absorbing apparatus 100 is configured to reduce vibrations generated by a semiconductor manufacturing apparatus SMA. For example, the vibration absorbing apparatus 100 may include a pair of dynamic vibration absorbers (e.g., 300 and 400) each including an elastic body and a mass body. The dynamic vibration absorbers may absorb vibrations generated by the semiconductor manufacturing apparatus SMA and transmitted to the base 200. As a result, the dynamic vibration absorbers may vibrate instead of (or in conjunction with) the semiconductor manufacturing apparatus SMA, thereby reducing its vibrations. Furthermore, the mass bodies of the pair of dynamic vibration absorbers may collide with each other, dissipating the vibration energy of the semiconductor manufacturing apparatus SMA, and further reducing its vibrations.

The semiconductor manufacturing apparatus SMA may include various apparatus used in the semiconductor manufacturing process, such as a wafer manufacturing process, an oxidation process, a photolithography process, an etching process, a deposition process, a plating process, a doping process, a packaging process, an inspection process, etc. For example, the semiconductor manufacturing apparatus SMA may include a polishing apparatus, a sawing apparatus, a cleaning apparatus, an etching apparatus, a deposition apparatus, a sputtering apparatus, an attachment apparatus, and the like used to manufacture a semiconductor device. Further, the semiconductor manufacturing apparatus SMA may include an inspection apparatus and a metrology apparatus used to test the semiconductor device.

In example embodiments, the base 200 may include a base plate 210 provided on the surface IS of the semiconductor manufacturing apparatus SMA and a plurality of fixing members 220 that fix the base plate 210 to the semiconductor manufacturing apparatus SMA. For example, the base plate 210 may include a plurality of holes in a peripheral region. The plurality of fixing members 220 may be coupled with the plurality of holes to integrally couple the base plate 210 to the semiconductor manufacturing apparatus SMA. Thus, when the semiconductor manufacturing apparatus SMA generates vibrations, the base plate 210 may transmit these vibrations in unison with the semiconductor manufacturing apparatus SMA.

Although only a square-shaped base plate 210 and a few fixing 220 members are illustrated in the figures, it will be understood that the number, shape, size and arrangement of the base plate 210 and the fixing members 220 are provided as an example, so the present inventive concept is not limited thereto.

The base plate 210 may include a first surface 212 and a second surface 214 extending in a vertical direction VD and facing each other. For example, the first surface 212 may face outward and the second surface 214 may face the surface IS of the semiconductor manufacturing apparatus SMA. In the figures, the base plate 210 may extend in a vertical direction, but it will be understood that the present inventive concept is not limited thereto. Accordingly, the extension direction of the base plate 210 may vary depending on the surface IS on which the base plate 210 is installed on the semiconductor manufacturing apparatus SMA.

The base plate 210 may include a base hole array BHA in a central region. The base hole array BHA may include a plurality of holes penetrating from the first surface 212 to the second surface 214 of the base plate 210.

In example embodiments, the first dynamic vibration absorber 300 may include a first elastic body 310 fastened to the base plate 210 and a first mass body 320 provided on the first elastic body 310. Further, the first dynamic vibration absorber 300 may include a first elastic body connector 313 configured to connect the first elastic body 310 to the base plate 210 and a first mass body connector 323 configured to connect the first mass body 320 to the first elastic body 310. For example, the first dynamic vibration absorber 300 may be configured to vibrate either independently or in conjunction with the semiconductor manufacturing apparatus SMA to dampen its vibrations.

While the figures illustrate that the first dynamic vibration absorber 300 is mounted on the base 200, it will be understood that the present inventive concept is not limited to this. For example, the first dynamic vibration absorber 300 may be mounted directly on the surface IS of the semiconductor manufacturing apparatus SMA.

The first elastic body 310 may include a first fixed end portion SP1 fastened to the base plate 210 and a first free end portion VP1 extending from the first fixed end portion SP1 in a first horizontal direction HD1. For example, the first elastic body 310 may be a beam-shaped structure including a metallic material. The first elastic body 310 may be a cantilever beam, with a first end fixed to the base plate 210 and a second end, opposite the first end, configured to move in a particular direction. For example, the metallic material may include aluminum (Al). However, the present inventive concept is not limited thereto, so the size, shape, material, etc. of the first elastic body 310 may be varied.

For example, the first horizontal direction HD1 may be a direction parallel to the first surface 212 of the base plate 210, and a second horizontal direction HD2 may be a direction perpendicular to the first surface 212 of the base plate 210. Further, the first horizontal direction HD1 and the second horizontal direction HD2 may be perpendicular to the vertical direction VD.

The first elastic body 310 may include a first hole array HA1 at the first fixed end portion SP1 and a first guide SL1 at the first free end portion VP1 extending in the first horizontal direction HD1.

The first elastic body 310 may include a first surface 310a and a second surface 310b extending in the first horizontal direction HD1 and facing each other. Further, the first elastic body 310 may include a first side portion S31a located on the base plate 210 and a second side portion S31b opposite the first side portion S31a. The second side portion S31b may be located away from the base plate 210.

The first hole array HA1 may include a plurality of holes provided in a region adjacent to the first side portion S31a. The plurality of holes may be arranged in an array including a plurality of columns and a plurality of rows. Each of the plurality of holes may penetrate from the first surface 310a of the first elastic body 310 to the second surface 310b of the first elastic body 310.

The first elastic body 310 may have the first guide SL1 extending in the first horizontal direction HD1 at the first free end portion VP1. The first mass body 320 may be fastened to the first guide SL1 and configured to be positionally adjustable along the first guide SL1. For example, the first guide SL1 may be a groove configured to move the first mass body 320 in the first horizontal direction HD1.

The first guide SL1 may be provided in a region adjacent to the second side portion S31b of the first elastic body 310. The first guide SL1 may extend through the first surface 310a of the first elastic body 310 and penetrate the second surface S310b of the first elastic body 310. For example, the first guide SL1 may include a slit having a square shape. However, the present inventive concept is not limited thereto, so the size, shape, etc. of the first guide SL1 may be varied.

The first free end portion VP1 may extend from the first fixed end portion SP1 in the first horizontal direction HD1. Additionally, at least a portion of the first free end portion VP1 may protrude outward from a side portion of the base plate 210. A space may be provided between the portion of the first free end portion VP1 that protrudes away from the base plate 210 and the semiconductor manufacturing apparatus SMA. The space may accommodate the movement of the first free end portion VP1. For example, the space may allow the first free end portion VP1 to move in the second horizontal direction HD2.

The first free end portion VP1 may vibrate in a direction different from the first horizontal direction HD1. For example, the vibration direction of the first free end portion VP1 may be the second horizontal direction HD2 perpendicular to the first horizontal direction HD1. However, the present inventive concept is not limited to this, so the vibration direction may be varied.

The first elastic body connector 313 may include at least one first connection structure 313a adjacent to the first side portion S31a of the first elastic body 310 and at least one second connection structure 313b closer to the second side portion S31b of the first elastic body 310 than the first connection structure 313a.

The at least one first connection structure 313a may include a first through member EM1 and a pair of first fastening members FM1a, FM1b. For example, the first through member EM1 may include a bolt having an external engagement surface. The pair of first fastening members FM1a, FM1b may include a pair of nuts engageable with the external engagement surface of the first through member EM1.

The first through member EM1 may penetrate a portion of the base hole array BHA of the base plate 210 and the first hole array HA1 of the first elastic body 310, respectively. For example, the holes of the base hole array BHA and the holes of the first hole array HA1 may each be aligned along the second horizontal direction HD2. The first through member EM1 may penetrate the base plate 210 and the first elastic body 310 through the base hole array BHA and the first hole array HA1.

The pair of first fastening members FM1a, FM1b may be engaged with the end portions of the first through member EM1 and may restrict the movement of the base plate 210 and the first elastic body 310, respectively, thereby securing the first elastic body 310 to the base plate 210.

The at least one second connection structure 313b may be substantially the same as the at least one first connection structure 313a, except for its position in the first horizontal direction HD1. Thus, the at least one second connection structure 313b may also include a through member, which penetrates the base plate 210 and the first elastic body 310, and a pair of fastening members that engage with the through member.

The first mass body 320 may have a first surface 320a and a second surface 320b facing each other.

The first mass body 320 may have a first central hole H1 allocated in its central region, extending through the first surface 320a to the second surface 320b of the first mass body 320. The first central hole H1 may align with the first guide SL1 in the second horizontal direction HD2, forming a single continuous passage.

The first mass body 320 may include a first side portion S32a and a second side portion S32b facing each other. For example, the first mass body 320 may have a square shape when viewed in a plan view. The first mass body 320 may include a metallic material. For example, the first mass body 320 may include steel. However, the present inventive concept is not limited thereto, so the arrangement, material, shape, size, etc. of the first mass body 320 may be varied.

The first mass body connector 323 may include a third through member EM3 and a pair of third fastening members FM3a, FM3b. For example, the third through member EM3 may include a bolt having an external engagement surface. The pair of third fastening members FM3a, FM3b may include a pair of nuts engageable with the third through member EM3.

The third through member EM3 may penetrate the first guide SL1 of the first elastic body 310 and the first central hole H1 of the first mass body 320. For example, the first guide SL1 and the first central hole H1 may be aligned along the second horizontal direction HD2. The third through member EM3 may extend through the first elastic body 310 and the first mass body 320 via the first guide SL1 and the first central hole H1.

The pair of third fastening members FM3a, FM3b may be engaged with end portions of the third through member EM3, restricting the movement of the first elastic body 310 and the first mass body 320, thereby securing the first mass body 320 to the first elastic body 310.

The first mass body 320 may have a first distance L1 in the first horizontal direction HD1 from the first elastic body connector 313. For example, the first distance L1 may refer to the distance between the closest connection member of the first elastic body connector 313, specifically the at least one second connection structure 313b, and the first mass body connector 323 of the first mass body 320.

The first distance L1 of the first mass body 320 may be adjustable by moving the first mass body 320 along the first guide SL1 of the first elastic body 310. For example, the position of the first mass body 320 in the first horizontal direction HD1 can be modified by temporarily uncoupling the pair of third fastening members FM3a, FM3b and the third through member EM3, adjusting the position, and then recoupling the pair of third fastening members FM3a, FM3b and the third through member EM3.

The first dynamic vibration absorber 300 may have a first frequency W1, which corresponds to its natural frequency. For example, the natural frequency is the frequency at which a system vibrates when no external force is applied. The natural frequency may be determined by factors such as the mass of the first mass body 320, the first distance L1, the elastic modulus of the first elastic body 310, the moment of inertia of the first elastic body 310, or the like.

The first frequency W1 may change depending on the first distance L1 of the first mass body 320. For example, as the first distance L1 increases, the first frequency W1 may decrease, and as the first distance L1 decreases, the first frequency W1 may increase.

In example embodiments, the second dynamic vibration absorber 400 may include a second elastic body 410 fastened to the base plate 210 and a second mass body 420 provided on the second elastic body 410. Further, the second dynamic vibration absorber 400 may include a second elastic body connector 413 configured to connect the base plate 210 and the second elastic body 410 and a second mass body connector 423 configured to connect the second elastic body 410 and the second mass body 420. For example, the second dynamic vibration absorber 400 may be configured to vibrate either independently or in conjunction with the semiconductor manufacturing apparatus SMA to dampen its vibrations when the semiconductor manufacturing apparatus SMA is in operation.

While the figures illustrate that the second dynamic vibration absorber 400 is mounted on the base 200, it will be understood that the present inventive concept is not limited to this. Thus, the second dynamic vibration absorber 400 may be mounted directly on the surface IS of the semiconductor manufacturing apparatus SMA.

The second elastic body 410 may include a second fixed end portion SP2 that is coupled to the base plate 210 and a second free end portion VP2 that extends from the second fixed end portion SP2 in the first horizontal direction HD1. For example, the second elastic body 410 may be a beam-shaped structure including a metallic material. The second elastic body 410 may be a cantilever beam with a first end portion fixed to the base plate 210 and a second end portion, opposite to the first end portion, configured to allow movement in a particular direction. For example, the metallic material may include aluminum (Al). However, the present inventive concept is not limited thereto, so the size, shape, material, etc. of the second elastic body 410 may be varied.

The second elastic body 410 may include a second hole array HA2 at the second fixed end portion SP2 and a second guide SL2 extending in the first horizontal direction HD1 at the second free end portion VP2.

The second elastic body 410 may include a first surface 410a and a second surface 410b extending in the first horizontal direction HD1 and facing each other. Further, the second elastic body 410 may include a first side portion S41a located on the base plate 210 and a second side portion S41b opposite the first side portion S41a. The second side portion S41b may be located away from the base plate 210.

The second hole array HA2 may include a plurality of holes provided in a region adjacent to the first side portion S41a. The plurality of holes may be arranged in an array including a plurality of columns and a plurality of rows. Each of the plurality of holes may penetrate from the first surface 410a of the second elastic body 410 to the second surface 410b of the second elastic body 410.

The second elastic body 410 may include the second guide SL2 extending in the first horizontal direction HD1 at the second free end portion VP2. The second mass body 420 may be engaged with the second guide SL2 to allow positional adjustment along the second guide SL2. For example, the second guide SL2 may be a groove designed to enable movement of the second mass body 420 in the first horizontal direction HD1.

The second guide SL2 may be provided in an area adjacent to the second side portion S41b of the second elastic body 410, and may penetrate the second surface S410b of the second elastic body 410 from the first surface 410a of the second elastic body 410. For example, the second guide SL2 may include a slit having a square shape. However, the present inventive concept is not limited thereto, so the size, shape, etc. of the second guide SL2 may be varied.

The second free end portion VP2 may extend from the second fixed end portion SP2 in the first horizontal direction HD1, with at least a portion of the second free end portion VP2 protruding outward from one side of the base plate 210. A space may be provided between this portion of the second free end portion VP2 and the semiconductor manufacturing apparatus SMA, allowing for its movement. For example, the space may enable movement of the second free end portion VP2 in the second horizontal direction HD2.

The second free end portion VP2 may oscillate in a direction different from the first horizontal direction HD1. For example, the oscillation direction of the second free end portion VP2 may be in the second horizontal direction HD2 perpendicular to the first horizontal direction HD1. However, the present inventive concept is not limited thereto, so that the oscillation direction may be varied.

The second elastic body connector 413 may include at least one third connection structure 413a adjacent to the first side portion S41a of the second elastic body 410 and at least one fourth connection structure 413b closer to the second side portion S41b of the second elastic body 410 that the at least one third connection structure 413a.

The at least one third connection structure 413a may include a second through member EM2 and a pair of second fastening members FM2a and FM2b. For example, the second through member EM2 may include a bolt having an external engagement surface. The pair of second fastening members FM2a and FM2b may include a pair of nuts engageable with the second through member EM2.

The second through member EM2 may penetrate a portion of the base hole array BHA of the base plate 210 and the second hole array HA2 of the second elastic body 410, respectively. For example, the holes in the base hole array BHA and the second hole array HA2 may aligned along the second horizontal direction HD2. The second through member EM2 may pass through the base plate 210 and the second elastic body 410 via the base hole array BHA and the second hole array HA2.

The pair of second fastening members FM2a, FM2b may be engaged with end portions of the second through member EM2, restricting the movement of the base plate 210 and the second elastic body 410, thereby securing the second elastic body 410 to the base plate 210.

The at least one fourth connection structure 413b may be substantially the same as the at least one third connection structure 413a, except for its position in the first horizontal direction HD1. Thus, the at least one fourth connection structure 413b may also include a through member, which penetrates the base plate 210 and the second elastic body 410, and a pair of fastening members that engage with the through member.

The second mass body 420 may include a first surface 420a and a second surface 420b facing each other.

The second mass body 420 may include a second central hole H2 allocated in its central region, extending from the first surface 420a to the second surface 420b of the second mass body 420. The second central hole H2 may align with the second guide SL2 of the second elastic body 410 in the second horizontal direction HD2, forming a single continuous passage.

The second mass body 420 may include a first side portion S42a and a second side portion S42b facing each other. The first side portion S42a of the second mass body 420 may overlap with the first mass body 320. For example, the second mass body 420 may have a square shape when viewed in a plan view. The second mass body 420 may include a metallic material. For example, the second mass body 420 may include steel. However, the present inventive concept is not limited thereto, so the arrangement, material, shape, size, etc. of the second mass body 420 may be varied.

The second mass body connector 423 may include a fourth through member EM4 and a pair of fourth fastening members FM4a, FM4b. For example, the fourth through member EM4 may include a bolt having an external engagement surface. The pair of fourth fastening members FM4a, FM4b may include a pair of nuts engageable with the external engagement surface of the fourth through member EM4.

The fourth through member EM4 may penetrate both the second guide SL2 of the second elastic body 410 and the second central hole H2 of the second mass body 420. For example, the second guide SL2 and the second central hole H2 may be aligned along the second horizontal direction HD2. The fourth through member EM4 may pass through the second elastic body 410 and the second mass body 420 via the second guide SL2 and the second central hole H2.

The pair of fourth fastening members FM4a, FM4b may be engaged with end portions of the fourth through member EM4, restricting the movement of both the second elastic body 410 and the second mass body 420, thereby securing the second mass body 420 to the second elastic body 410.

The second mass body 420 may have a second distance L2 in the first horizontal direction HD1 from the second elastic body connector 413. For example, the second distance L2 may refer to the distance between the closest connection member of the second elastic body connector 413, specifically the at least one fourth connection structure 413b, and the second mass body connector 423 of the second mass body 420.

The second distance L2 of the second mass body 420 may be adjustable by moving the second mass body 420 along the second guide SL1 of the second elastic body 410. For example, the position of the second mass body 420 in the first horizontal direction HD1 can be adjusted by temporarily uncoupling the pair of fourth fastening members FM4a, FM4b and the fourth through member EM4, repositioning the second mass body 420, and then recoupling the pair of fourth fastening members FM4a, FM4b and the fourth through member EM4.

The second dynamic vibration absorber 400 may have a second frequency W2, which corresponds to its natural frequency. For example, the natural frequency is the frequency at which a particular system vibrates when no external force is applied to the particular system. The natural frequency may be determined by factors such as the mass of the second mass body 420, the second distance L2, the modulus of elasticity of the second elastic body 410, the moment of inertia of the second elastic body 410, or similar parameters.

The second frequency W2 may vary depending on the second distance L2 of the second mass body 420. For example, as the second distance L2 increases, the second frequency W2 may decrease, and as the second distance L2 decreases, the second frequency W2 may increase. The first elastic body 310 may have a first thickness T1 and the second elastic body 410 may have a second thickness T2. For example, the second thickness T2 may be larger than the first thickness T1. However, as the present inventive concept is not limited thereto, the second thickness T2 may be the same as or less than the first thickness T1.

The first mass body 320 may have a first height HE1 from the base plate 210. For example, the first height HE1 may be a distance from the first surface 212 of the base plate 210 to the second surface 320b of the first mass body 320. The first height HE1 may be measured in the second horizontal direction HD2. The second mass body 420 may have a second height HE2 from the base plate 210. For example, the second height HE2 may be a distance from the first surface 212 of the base plate 210 to the second surface 420b of the second mass body 420. The second height HE2 may be measured in the second horizontal direction HD2.

The second height HE2 of the second mass body 420 may be greater than the first height HE1 of the first mass body 320. Thus, at least a portion of the second mass body 420 may be located on an upper portion of the first mass body 320. In other words, a portion of the second mass body 420 may be disposed above the first mass body 320. However, as the present inventive concept is not limited thereto, the second height HE2 may be less than the first height HE1. In this case, at least a portion of the second mass body 420 may be located at a lower portion of the first mass body 320. In other words, a portion of the second mass body 420 may be disposed below the first mass body 320.

The second dynamic vibration absorber 400 may be disposed on the first surface 212 of the base plate 210, adjacent to the first dynamic vibration absorber 300, such that the second mass body 420 partially overlaps the first mass body 320 of the first dynamic vibration absorber 300.

The first mass body 320 and the second mass body 420 may respectively extend toward each other such that the first mass body 320 and the second mass body 420 are overlapped with each other. In other words, the first mass body 320 and the second mass body 420 may extend toward each other, resulting in an overlapping configuration between the two mass bodies. For example, the first mass body 320 may have a first overlap portion OP1 in a first overlap region OR1 adjacent to the first side portion S32a of the first mass body 320, and the second mass body 420 may have a second overlap portion OP2 in a second overlap region OR2 adjacent to the first side portion S42a of the second mass body 420.

The first overlap portion OP1 and the second overlap portion OP2 may be adjacent to each other. For example, the first overlap portion OP1 and the second overlap portion OP2 may be spaced apart from each other to form a gap G between the first overlap portion OP1 and the second overlap portion OP2. For example, the first overlap portion OP1 and the second overlap portion OP2 may be spaced apart in the second horizontal direction HD2 such that the second surface 310b of the first mass body 320 and the first surface 410a of the second mass body 420 face each other. Alternatively, the first overlap portion OP1 and the second overlap portion OP2 may be in contact with each other.

The first overlap portion OP1 and the second overlap portion OP2 may be regions which collide with each other when vibrations occur in the semiconductor manufacturing apparatus SMA. In other words, the first overlap portion OP1 and the second overlap portion OP2 may collide with each other when vibrations occur in the semiconductor manufacturing apparatus SMA.

For example, when vibrations occur in the semiconductor manufacturing apparatus SMA, they may be transmitted to the first elastic body 310 and the second elastic body 410, causing both to vibrate in the second horizontal direction HD2, respectively. Along with these vibrations, the first mass body 320 and the second mass body 420 may also vibrate in the second horizontal direction HD2. As the vibrations of the semiconductor manufacturing apparatus SMA are transmitted to the elastic bodies and mass bodies, this interaction helps to reduce the overall vibration of the semiconductor manufacturing apparatus SMA.

During this process, the first overlap portion OP1 of the first mass body 320 and the second overlap portion OP2 of the second mass body 420 may collide with each other based on the vibrations of the first elastic body 310 and the second elastic body 410. The collisions may generate sound, heat, and other effects, dissipating the vibration energy stored in the first elastic body 310 and the second elastic body 410. As a result, the vibrations of the first elastic body 310 and the second elastic body 410 are reduced, thereby further reducing the vibrations of the semiconductor manufacturing apparatus SMA.

The first frequency W1 of the first dynamic vibration absorber 300 and the second frequency W2 of the second dynamic vibration absorber 400 may be set based on a target frequency W0, which corresponds to the frequency of the vibrations generated by the semiconductor manufacturing apparatus SMA. For example, the first frequency W1 may be equal to the target frequency W0 or greater than the target frequency W0, and the second frequency W2 may be equal to the target frequency W0 or less than the target frequency W0. Alternatively, the first frequency W1 may be equal to the target frequency W0 or less than the target frequency W0 and the second frequency W2 may be equal to the target frequency W0 or greater than the target frequency W0.

Although only a few holes and slits are illustrated in the figures, it will be understood that the size, number, shape and arrangement of the holes and slits are provided as examples, so the present inventive concept is not limited thereto.

Furthermore, it will be understood that the first and second elastic body connectors 313, 413 and the first and second mass body connectors 323, 423 are provided as an example, so the present inventive concept is not limited thereto. Accordingly, the structure, arrangement, size, etc. of the first and second elastic body connectors 313, 413 and the first and second mass body connectors 323, 423 may be varied.

As described above, the vibration absorbing apparatus 100 for a semiconductor manufacturing apparatus may include the base plate 210 secured to the semiconductor manufacturing apparatus SMA, the first dynamic vibration absorber 300 having the first elastic body 310 coupled to the base plate 210 and the first mass body 320 coupled to the first elastic body 310, and a second dynamic vibration absorber 400 including the second elastic body 410 coupled to the base plate 210 adjacent to the first elastic body 310 and the second mass body 420 coupled to the second elastic body 410.

The first mass body 320 and the second mass body 420 may be capable of colliding with each other to reduce vibrations at certain frequencies that are applied to the base plate 210 from the semiconductor manufacturing apparatus SMA. In other words, the first mass body 320 and the second mass body 420 may collide with each other to reduce vibrations at certain frequencies transmitted to the base plate 210 from the semiconductor manufacturing apparatus SMA.

Accordingly, the vibration-absorbing apparatus 100 for the semiconductor manufacturing apparatus can effectively absorb vibrations across a relatively wide frequency range. Additionally, the collision between the first mass body 320 and the second mass body 420 dissipates vibration energy, thereby significantly reducing the vibrations generated by the semiconductor manufacturing apparatus.

Further, the first mass body 320 can be adjusted along the first guide SL1 of the first elastic body 310, and the second mass body 420 can be adjusted along the second guide SL2 of the second elastic body 410.

Accordingly, the vibration absorbing apparatus 100 for the semiconductor manufacturing apparatus may easily change its set frequency (or natural frequency) to respond to vibrations generated by the semiconductor manufacturing apparatus.

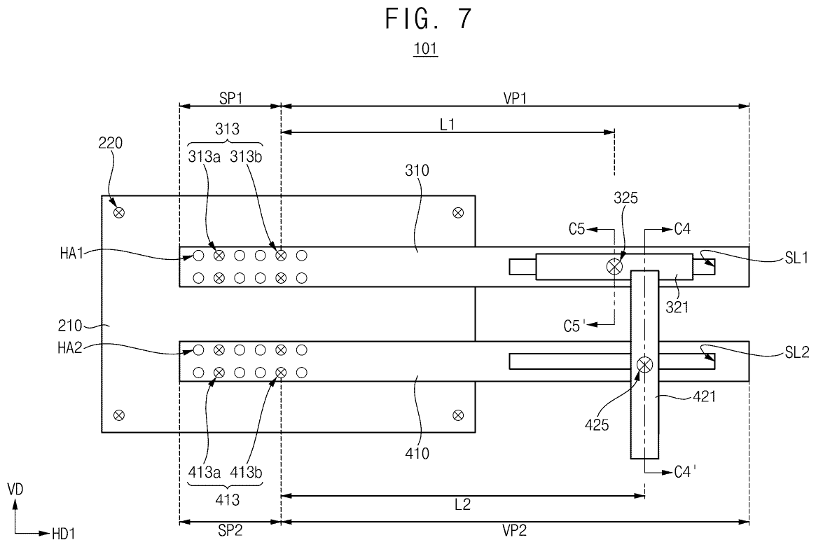

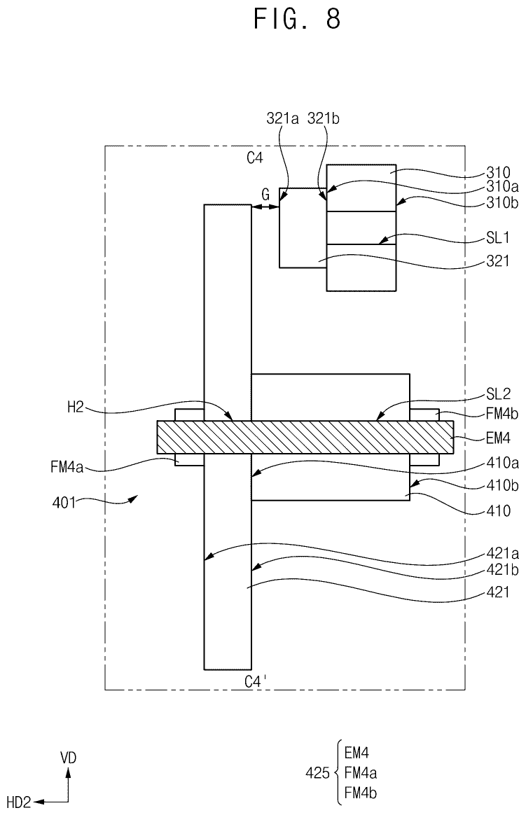

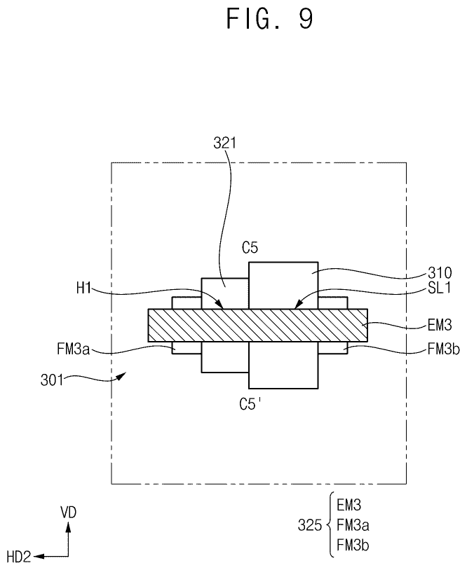

FIG. 7 a plan view illustrating a vibration absorbing apparatus in accordance with example embodiments of the present inventive concept. FIG. 8 is a cross-sectional view taken along the line C4-C4′ in FIG. 7. FIG. 9 is a cross-sectional view taken along the line C5-C5′ in FIG. 7.

Referring to FIGS. 7 to 9, a vibration absorbing apparatus 101 for a semiconductor manufacturing apparatus may include a base 200 provided on a surface IS of a semiconductor manufacturing apparatus SMA, a third dynamic vibration absorber 301 provided on the base 200, and a fourth dynamic vibration absorber 401 provided on the base 200 adjacent to the third dynamic vibration absorber 301. In addition, the vibration absorbing apparatus 101 for a semiconductor manufacturing device may further include a cover 600 surrounding the base 200, the third dynamic vibration absorber 301, and the fourth dynamic vibration absorber 401 to physically protect the base 200, the third dynamic vibration absorber 301, and the fourth dynamic vibration absorber 401 from external impact.

The vibration absorbing apparatus 101 illustrated in FIGS. 7 to 9 is substantially identical to the vibration absorbing apparatus 100 described in FIGS. 1 to 6, with the exception of the third dynamic vibration absorber 301 and the fourth dynamic vibration absorber 401, so identical components are denoted by the same reference numerals and repeated descriptions of identical components are omitted.

In example embodiments, the third dynamic vibration absorber 301 may include a first elastic body 310 coupled to the base plate 210 and a third mass body 321 provided on the first elastic body 310. Furthermore, the third dynamic vibration absorber 301 may include a first elastic body connector 313 configured to connect the base plate 210 and the first elastic body 310 and a third mass body connector 325 configured connect the first elastic body 310 and the third mass body 321. For example, the third dynamic vibration absorber 301 may be designed to vibrate either independently or in conjunction with the semiconductor manufacturing apparatus SMA to dampen its vibrations when the semiconductor manufacturing apparatus SMA experiences vibration.

While the figures illustrate that the third dynamic vibration absorber 301 is mounted on the base 200, it will be understood that the present inventive concept is not limited to this. Thus, the third dynamic vibration absorber 301 may be mounted directly on the surface IS of the semiconductor manufacturing apparatus SMA.

The first elastic body 310 may include a first fixed end portion SP1 that is coupled to the base plate 210 and a first free end portion VP1 extending from the first fixed end portion SP1 in the first horizontal direction HD1. For example, the first elastic body 310 may include a beam structure including a metallic material.

The first elastic body 310 may include a first hole array HA1 at the first fixed end portion SP1 and a first guide SL1 extending in the first horizontal direction HD1 at the first free end portion VP1.

The third mass body 321 may have a first surface 321a and a second surface 321b facing each other. The third mass body 321 may have a first central hole H1 at a central portion penetrating from the first surface 321a to the second surface 321b of the first mass body 321. The first central hole H1 may be aligned in the second horizontal direction HD2 with the first guide SL1 of the first elastic body 310 to form a single passage.

The third mass body connector 325 may include a third through member EM3 and a pair of third fastening members FM3a, FM3b. For example, the third through member EM3 may include a bolt having an external engagement surface. The pair of third fastening members FM3a, FM3b may include a pair of nuts engageable with the external engagement surface of the third through member EM3.

The third mass body 321 may have a first distance L1 in the first horizontal direction HD1 from the first elastic body connector 313. For example, the first distance L1 refers to the distance between the at least one second connection structure 313b, which is the closest connecting member of the first elastic body connector 313 and the third mass body connector 325 of the third mass body 321. For example, the first distance L1 of the third mass body 321 may be adjustable by moving the third mass body 321 along the first guide SL1 of the first elastic body 310.

The third mass body 321 may extend along the first horizontal direction HD1. For example, the third mass body 321 may have a square shape with its length in the first horizontal direction HD1 being greater than its length in the vertical direction VD. The third mass body 321 may include a metallic material. For example, the third mass body 321 may include steel. However, the present inventive concept is not limited thereto, so the arrangement, material, shape, size, etc. of the third mass body 321 may be varied.

In example embodiments, the fourth dynamic vibration absorber 401 may include a second elastic body 410 coupled to the base plate 210 and a fourth mass body 421 provided on the second elastic body 410. Further, the fourth dynamic vibration absorber 401 may include a second elastic body connector 413 configured to connect the base plate 210 to the second elastic body 410 and a fourth mass body connector 425 configured to connect the second elastic body 410 to the fourth mass body 421. For example, the fourth dynamic vibration absorber 401 may be designed to vibrate either independently or in conjunction with the semiconductor manufacturing apparatus SMA to dampen its vibrations when the semiconductor manufacturing apparatus SMA experiences vibration.

Although figures illustrate that the fourth dynamic vibration absorber 401 is mounted on the base 200, it will be understood that the present inventive concept is not limited thereto. Accordingly, the fourth dynamic vibration absorber 401 may be mounted directly on the surface IS of a semiconductor manufacturing apparatus SMA.

The second elastic body 410 may include a second fixed end portion SP2 that is coupled to the base plate 210 and a second free end portion VP2 that extends from the second fixed end portion SP2 in the first horizontal direction HD1. For example, the second elastic body 410 may have a beam structure including a metallic material.

The second elastic body 410 may include a second hole array HA2 at the second fixed end portion SP2 and a second guide SL2 at the second free end portion VP2 extending in the first horizontal direction HD1.

The fourth mass body 421 may include a first surface 421a and a second surface 421b facing each other. The fourth mass body 421 may have a second central hole H2 at a central portion penetrating from the first surface 421a to the second surface 421b of the fourth mass body 421. The second central hole H2 may be aligned in the second horizontal direction HD2 with the second guide SL2 of the second elastic body 410 to form a single passage.

The fourth mass body connector 425 may include a fourth through member EM4 and a pair of fourth fastening members FM4a, FM4b. For example, the fourth through member EM4 may include a bolt having an external engagement surface. The pair of fourth fastening members FM4a, FM4b may include a pair of nuts engageable with the external engagement surface of the fourth through member EM4.

The fourth mass body 421 may have a second distance L2 in the first horizontal direction HD1 from the fourth elastic body connector 415. For example, the second distance L2 may refer to the distance between the at least one fourth connection structure 413b, which is the closest connection member of the second elastic body connector 413, and the fourth mass body connector 425 of the fourth mass body 421. The second distance L2 of the fourth mass body 421 may be adjustable by moving the fourth mass body 421 along the second guide SL2 of the second elastic body 410.

The fourth mass body 421 may extend along the vertical direction VD. For example, the fourth mass body 421 may have a square shape with its length in the vertical direction VD being greater than its length in the first horizontal direction HD1. The fourth mass body 421 may include a metallic material. For example, the fourth mass body 421 may include steel. However, the present inventive concept is not limited thereto, so the arrangement, material, shape, size, etc. of the fourth mass body 421 may be varied.

The fourth mass body 421 may extend over the upper portion of the third mass body 321 such that the fourth mass body 421 is at least partially overlapped with the third mass body 321. For example, the fourth mass body 421 may extend from the second guide SL2 of the second elastic body 410 to the first guide SL1 of the first elastic body 310.

Accordingly, the third mass body 321 may extend in the first horizontal direction HD1 and the fourth mass body 421 may extend over the upper portion of the third mass body 321. This configuration allows the first distance L1 of the third mass body 321 and the second distance L2 of the fourth mass body 421 to be adjusted over a wider range.

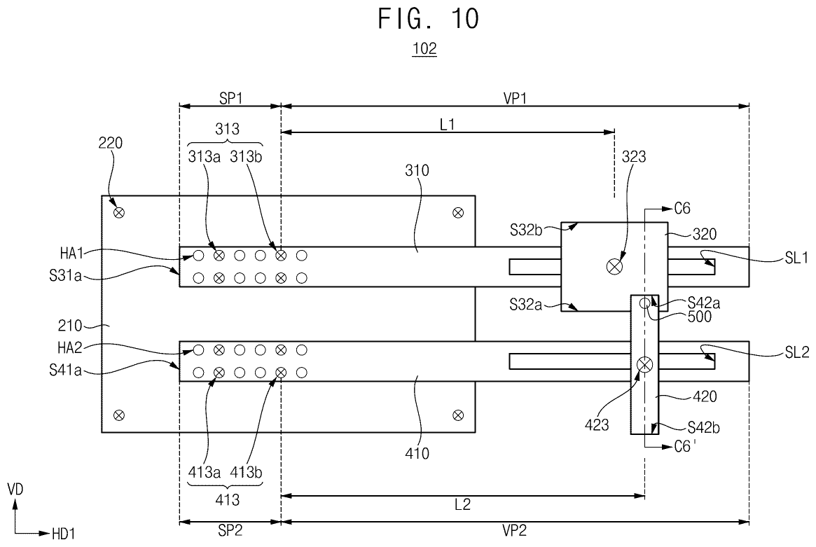

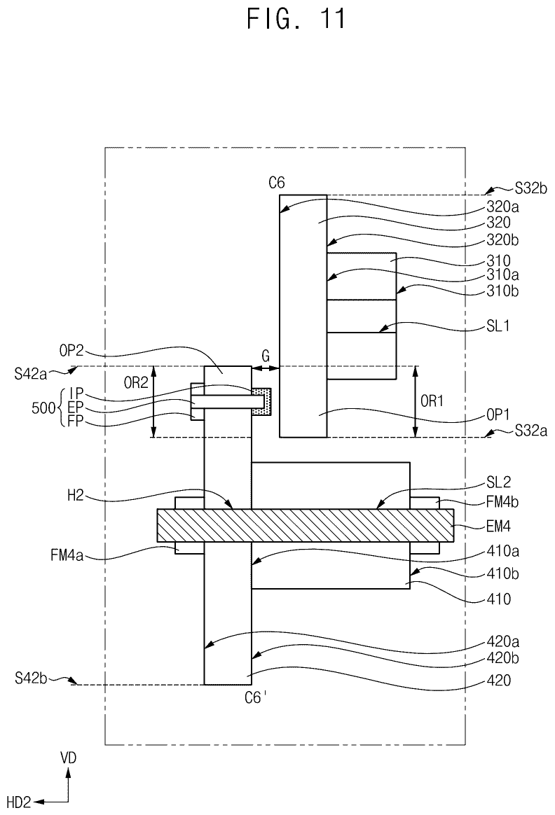

FIG. 10 a plan view illustrating a vibration absorbing apparatus in accordance with example embodiments. FIG. 11 is a cross-sectional view taken along the line C6-C6′ in FIG. 10.

Referring to FIGS. 10 and 11, a vibration absorbing apparatus 102 for a semiconductor device may include a base 200 provided on a surface IS of a semiconductor manufacturing apparatus SMA, a first dynamic vibration absorber 300 provided on the base 200, and a second dynamic vibration absorber 400 provided on the base 200 adjacent to the first dynamic vibration absorber 300. The vibration absorbing apparatus 102 for a semiconductor manufacturing device may further include a cover 600 surrounding the base 200, the first dynamic vibration absorber 300, and the second dynamic vibration absorber 400 to physically protect the base 200, the first dynamic vibration absorber 300, and the second dynamic vibration absorber 400 from external impact. In addition, the vibration absorbing apparatus 102 for a semiconductor manufacturing device may further include a first impact portion 500 provided between the first dynamic vibration absorber 300 and the second dynamic vibration absorber 400.

The vibration absorbing apparatus 102 illustrated in FIGS. 10 and 11 is substantially identical to the vibration absorbing apparatus 100 described in FIGS. 1 to 6 with the exception of the first impact portion 500, so identical components are denoted by the same reference numerals and repeated descriptions of identical components are omitted.

In example embodiments, the first impact portion 500 may be provided at the end portion of at least one of the first mass body 320 and the second mass body 420. The first impact portion 500 may be positioned within a gap G between the first dynamic vibration absorber 300 and the second dynamic vibration absorber 400. The first impact portion 500 may be designed to collide with at least one of the first mass body 320 or the second mass body 420, effectively dissipating vibration energy.

The first impact portion 500 may include an extension member EP provided in the second overlap portion OP2 to penetrate the second mass body 420, an impact member IP provided on a first end of the extension member EP facing the first mass body 320, and a joining member FP provided on a second end of the extension member EP. For example, the extension member EP may include a bolt having an external engagement surface. The joining member FP may include a nut engageable with the extension member EP.

The impact member IP may be fixed to the first end of the extension member EP and may collide with the first mass body 320 in response to the movement of the first elastic body 310 and the second elastic body 410. The impact member IP may be made of a material that effectively dissipates vibration energy. For example, the impact member IP may include a rubber material, a glass material, a metal material, or the like.

Accordingly, the first impact portion 500 may dissipate vibration energy by generating heat, sound, and other effects, thereby effectively reducing the vibrations of the semiconductor manufacturing apparatus SMA.

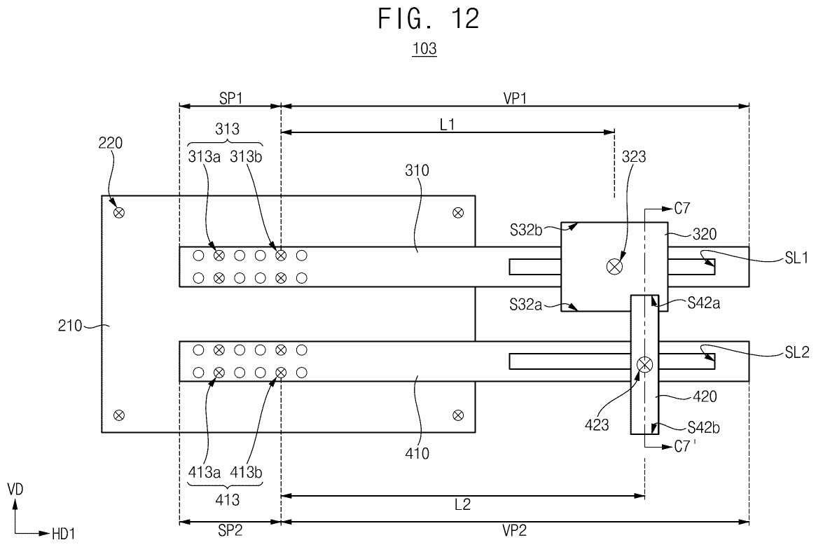

FIG. 12 a plan view illustrating a vibration absorbing apparatus in accordance with example embodiments of the present inventive concept.

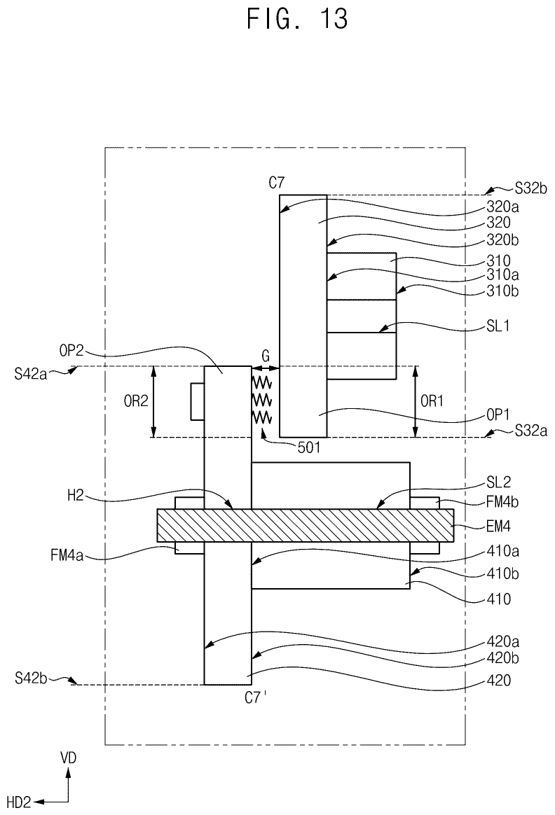

FIG. 13 is a cross-sectional view taken along the line C7-C7′ in FIG. 12.

Referring to FIGS. 12 and 13, a vibration absorbing apparatus 103 for a semiconductor device may include a base 200 provided on a surface IS of a semiconductor manufacturing apparatus SMA, a first dynamic vibration absorber 300 provided on the base 200, and a second dynamic vibration absorber 400 provided on the base 200 adjacent to the first dynamic vibration absorber 300. Further, the vibration absorbing apparatus 103 for a semiconductor manufacturing device may further include a cover 600 surrounding the base 200, the first dynamic vibration absorber 300, and the second dynamic vibration absorber 400 to physically protect the base 200, the first dynamic vibration absorber 300, and the second dynamic vibration absorber 400 from external impact. In addition, the vibration absorbing apparatus 103 for a semiconductor manufacturing device may further include a second impact portion 501 provided between the first dynamic vibration absorber 300 and the second dynamic vibration absorber 400.

The vibration absorbing apparatus 103 illustrated in FIGS. 12 and 13 is substantially the same as the vibration absorbing apparatus 100 described in FIGS. 1 to 6, except for the second impact portion 501, so identical components are denoted by the same reference numerals, and repeated descriptions of identical components are omitted.

In example embodiments, the second impact portion 501 may be provided on a first end portion of either the first mass body 320 or the second mass body 420. The second impact portion 501 may be positioned within a gap G between the first dynamic vibration absorber 300 and the second dynamic vibration absorber 400. The second impact portion 501 may be designed to collide with either the first mass body 320 or the second mass body 420 to effectively dissipate vibration energy.

The second impact portion 501 may include an elastic body array positioned on the second overlap OP2 of the second mass body 420. For example, the elastic body array may include a plurality of springs arranged in a plurality of columns and rows within the second overlap region OR2. These springs may directly collide with the first mass body 320, allowing the duration and magnitude of the collision to be adjusted.

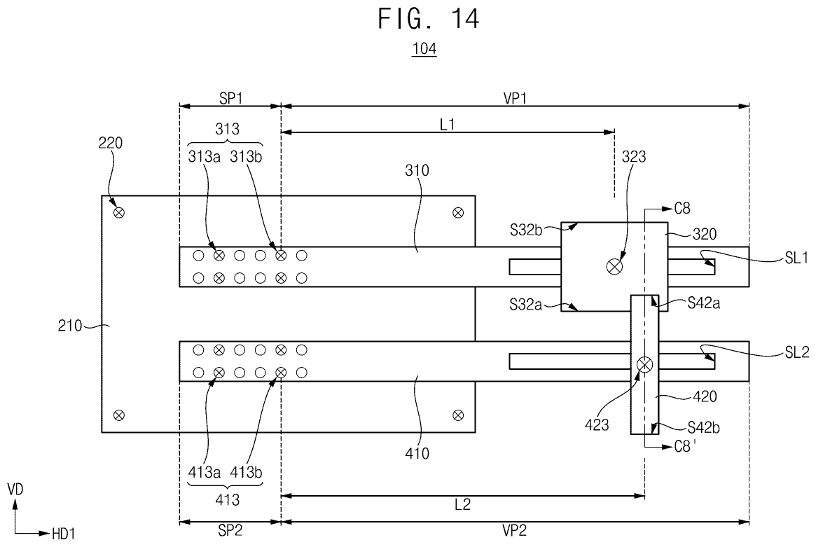

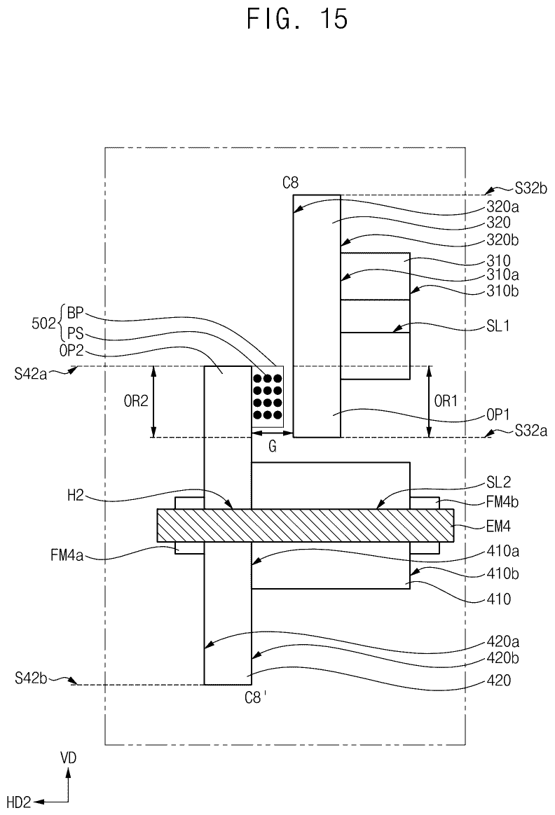

FIG. 14 a plan view illustrating a vibration absorbing apparatus in accordance with example embodiments. FIG. 15 is a cross-sectional view taken along the line C8-C8′ in FIG. 14.

Referring to FIGS. 14 and 15, a vibration absorbing apparatus 104 for a semiconductor device may include a base 200 provided on a surface IS of a semiconductor manufacturing apparatus SMA, a first dynamic vibration absorber 300 provided on the base 200, and a second dynamic vibration absorber 400 provided on the base 200 adjacent to the first dynamic vibration absorber 300. The vibration absorbing apparatus 104 for a semiconductor manufacturing device may further include a cover 600 surrounding the base 200, the first dynamic vibration absorber 300, and the second dynamic vibration absorber 400 to physically protect the base 200, the first dynamic vibration absorber 300, and the second dynamic vibration absorber 400 from external impact. In addition, the vibration absorbing apparatus 104 for a semiconductor manufacturing device may further include a third impact portion 502 provided between the first dynamic vibration absorber 300 and the second dynamic vibration absorber 400.

The vibration absorbing apparatus 104 illustrated in FIGS. 14 and 15 is substantially identical to the vibration absorbing apparatus 100 described in FIGS. 1 to 6 with the exception of the third impact portion 502, so identical components are denoted by the same reference numerals, and repeated descriptions of identical components are omitted.

In example embodiments, the third impact portion 502 may be provided on a first end portion of either the first mass body 320 or the second mass body 420, such that the third impact portion 502 is located in a gap G between the two mass bodies. The third impact portion 502 may be designed to collide with either the first mass body 320 or the second mass body 420 to effectively dissipate vibration energy.

The third impact portion 502 may include a box portion BP located on the second overlap portion OP2 facing the first mass body 320 and a plurality of particle structures PS within the box portion BP. For example, the third impact portion 502 may include a particle impact damper (PID), which is a damper that reduces system vibrations by dissipating absorbed vibration energy through collisions of the particle structures PS.

The box portion BP may define an enclosed space, with the plurality of particle structures PS housed within this enclosed space.

The plurality of particle structures PS may move freely within the enclosed space, colliding with one another. These collisions may generate sound, heat, and other effects, dissipating the vibrational energy transferred to the third impact portion 502.

The material of the plurality of particle structures PS may be selected to effectively dissipate vibrational energy. For example, the plurality of particle structures PA may include a rubber material, a glass material, a metal material, or the like.

Accordingly, the third impact portion 503 may dissipate vibrational energy, thereby effectively reducing the vibrations of the semiconductor manufacturing apparatus SMA.

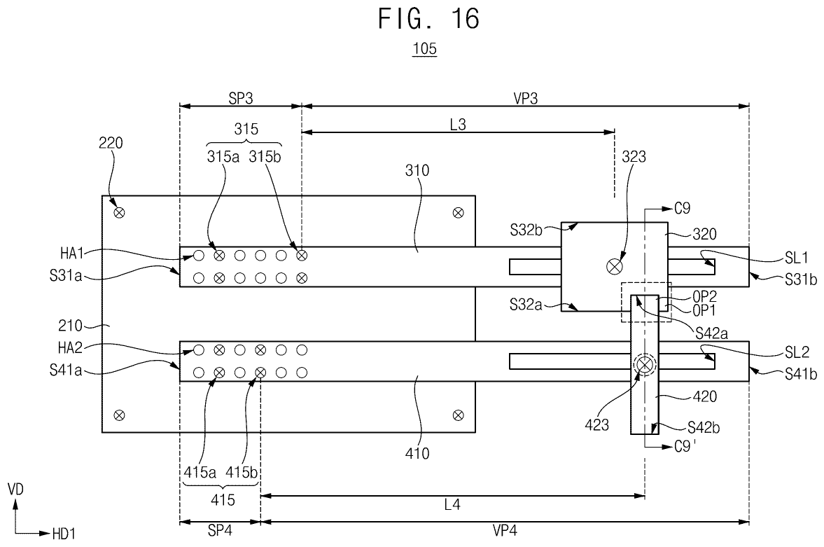

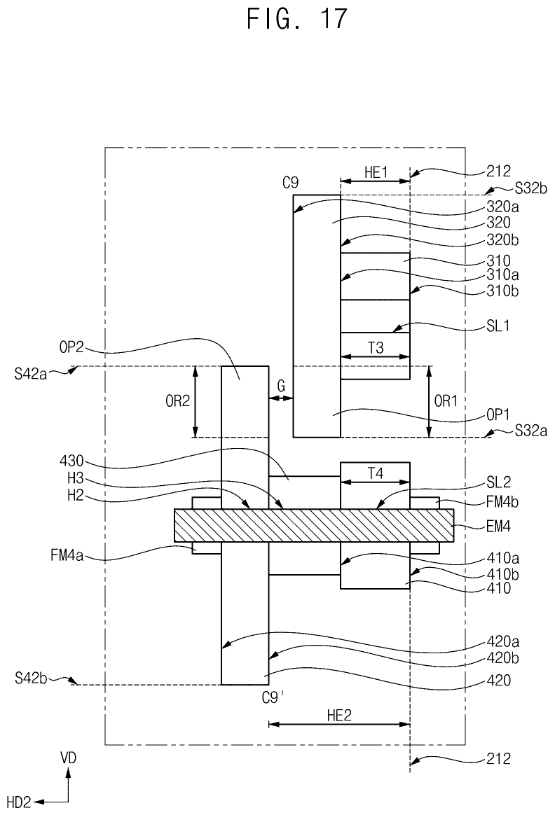

FIG. 16 a plan view illustrating a vibration absorbing apparatus in accordance with example embodiments. FIG. 17 is a cross-sectional view taken along the line C9-C9′ in FIG. 16.

Referring to FIGS. 16 and 17, a vibration absorbing apparatus 105 for a semiconductor device may include a base 200 provided on a surface IS of a semiconductor manufacturing apparatus SMA, a first dynamic vibration absorber 300 provided on the base 200, and a second dynamic vibration absorber 400 provided on the base 200 adjacent to the first dynamic vibration absorber 300. In addition, the vibration absorbing apparatus 105 for a semiconductor manufacturing device may further include a cover 600 surrounding the base 200, the first dynamic vibration absorber 300, and the second dynamic vibration absorber 400 to physically protect the base 200, the first dynamic vibration absorber 300, and the second dynamic vibration absorber 400 from external impact.

The vibration absorbing apparatus 105 illustrated in FIGS. 16 and 17 is substantially identical to the vibration absorbing apparatus 100 described in FIGS. 1 to 6 except for third and fourth elastic body connectors 315 and 415 and a gap adjustment structure 430, so identical components are denoted by the same reference numerals and repeated descriptions of identical components are omitted.

In example embodiments, the first dynamic vibration absorber 300 may include a first elastic body 310 coupled to the base plate 210 and a first mass body 320 provided on the first elastic body 310. Further, the first dynamic vibration absorber 300 may include the third elastic body connector 315 configured to connect the base plate 210 and the first elastic body 310 and a first mass body connector 323 configured to connect the first elastic body 310 and the first mass body 320.

While the figures illustrate that the first dynamic vibration absorber 300 is mounted on the base 200, it will be understood that the present inventive concept is not limited thereto. Accordingly, the first dynamic vibration absorber 300 may be mounted directly on the surface IS of a semiconductor manufacturing apparatus SMA.

The first elastic body 310 may include a third fixed end portion SP3 that is coupled to the base plate 210 and a third free end portion VP3 that extends from the third fixed end portion SP3 in the first horizontal direction HD1.

The first elastic body 310 may include a first hole array HA1 at the third fixed end portion SP3 and a first guide SL1 at the third free end portion VP3 extending in the first horizontal direction HD1.

The third elastic body connector 315 may include at least one fifth connection structure 315a adjacent to the first side portion S31a of the first elastic body 310 and at least one sixth connection structure 315b closer to the second side portion S31b of the first elastic body 310 that the at least one fifth connection structure 315a.

The at least one fifth connection structure 315a may include a first through member EM1 and a pair of first fastening members FM1a, FM1b. For example, the first through member EM1 may include a bolt having an external engagement surface. The pair of first fastening members FM1a, FM1b may include a pair of nuts engageable with the external engagement surface of the first through member EM1.

The first through member EM1 may penetrate a portion of the base hole array BHA of the base plate 210 and the first hole array HA1 of the first elastic body 310, respectively. For example, the holes of the base hole array BHA and the holes of the first hole array HA1 may each be aligned along the second horizontal direction HD2. The first through member EM1 may penetrate the base plate 210 and the first elastic body 310 through the base hole array BHA and the first hole array HA1.

The pair of first fastening members FM1a, FM1b may be engaged at end portions portion of the first through member EM1, thereby restricting the movement of the base plate 210 and the first elastic body 310 to fasten the first elastic body 310 to the base plate 210.

The at least one sixth connection structure 315b may be substantially identical to the at least one fifth connection structure 315a, except for the position of the at least one sixth connection structure 315b in the first horizontal direction HD1. Thus, the at least one sixth connection structure 315b may also include a through member, which penetrates the base plate 210 and the first elastic body 310, and a pair of fastening members that engage with the through member.

The first mass body 320 may include a first surface 320a and a second surface 320b facing each other. The first mass body 320 may include a first central hole H1 disposed in a central region and penetrating from the first surface 320a to the second surface 320b of the first mass body 320. The first central hole H1 may be aligned in the second horizontal direction HD2 with a first guide SL1 of the first elastic body 310 to form a single passage.

The first mass body connector 323 may include a third through member EM3 and a pair of third fastening members FM3a and FM3b. For example, the third through member EM3 may include a bolt having an external engagement surface. The pair of third fastening members FM3a and FM3b may include a pair of nuts engageable with the external engagement surface of the third through member EM3.

The first mass body 320 may have a third distance L3 in the first horizontal direction HD1 from the third elastic body connector 315. For example, the third distance L3 may refer to the distance between the at least one sixth connection structure 315b, which is the closest connection member of the third elastic body connector 315, and the first mass body connector 323 of the first mass body 320. For example, the third distance L3 of the first mass body 320 may be adjustable by moving the first mass body 320 along the first guide SL1 of the first elastic body 310.

In example embodiments, the second dynamic vibration absorber 400 may include a second elastic body 410 coupled to the base plate 210 and a second mass body 420 provided on the second elastic body 410. Further, the second dynamic vibration absorber 400 may include a fourth elastic body connector 415 configured to connect the base plate 210 to the second elastic body 410 and a second mass body connector 423 configured to connect the second elastic body 410 to the second mass body 420. The second dynamic vibration absorber 400 may further include a gap adjustment structure 430 configured to adjust a gap G between the first mass body 320 and the second mass body 420.

Although the figures illustrate that the second dynamic vibration absorber 400 is mounted on the base 200, it will be understood that the present inventive concept is not limited thereto. Accordingly, the second dynamic vibration absorber 400 may be mounted directly on the surface IS of a semiconductor manufacturing apparatus SMA.

The second elastic body 410 may include a fourth fixed end portion SP4 coupled to the base plate 210 and a fourth free end portion VP4 extending from the fourth fixed end portion SP4 in the first horizontal direction HD1.

The second elastic body 410 may include a second hole array HA2 at the fourth fixed end portion SP4 and a second guide SL2 at the fourth free end portion VP4 extending in the first horizontal direction HD1.

The fourth elastic body connector 415 may include at least one seventh connection structure 415a adjacent to the first side portion S41a of the second elastic body 410 and at least one eighth connection structure 415b closer to the second side portion S41b of the second elastic body 410 than the at least one seventh connection structure 415a.

The at least one seventh connection structure 415a may include a second through member EM2 and a pair of second fastening members FM2a and FM2b. For example, the second through member EM2 may include a bolt having an external engagement surface. The pair of second fastening members FM2a and FM2b may include a pair of nuts engageable with the external engagement surface of the first through member EM2.

The second through member EM2 may penetrate a portion of the base hole array BHA of the base plate 210 and the second hole array HA2 of the second elastic body 410, respectively. For example, the holes in the base hole array BHA and the holes in the second hole array HA2 may each be aligned along the second horizontal direction HD2. The second through member EM2 may penetrate the base plate 210 and the second elastic body 410 through the base hole array BHA and the second hole array HA2.

The pair of second fastening members FM2a and FM2b may be engaged at end portions of the second through member EM2, thereby restricting the movement of the base plate 210 and the second elastic body 410 to secure the second elastic body 410 to the base plate 210.

The at least one eighth connection structure 415b may be substantially the same as the at least one seventh connecting structure 415a, except for position of the at least one eighth connection structure 415b in the first horizontal direction HD1. Thus, the at least one eighth connection structure 415b may also include a through member, which penetrates the base plate 210 and the second elastic body 410, and a pair of fastening members that engage with the through member.

The second mass body 420 may have a first surface 420a and a second surface 420b facing each other. The second mass body 420 may have a second central hole H2 in a central region penetrating from the first surface 420a to the second surface 420b of the second mass body 420. The second central hole H2 may be aligned in the second horizontal direction HD2 with the second guide SL2 of the second elastic body 410 to form a single passage.

The second mass body connector 423 may include a fourth through member EM4 and a pair of fourth fastening members FM4 and FM4b. For example, the fourth through member EM4 may include a bolt having an external engagement surface. The pair of fourth fastening members FM4 and FM4b may include a pair of nuts engageable with the external engagement surface of the fourth through member EM4.

The second mass body 420 may have a fourth distance L4 in the first horizontal direction HD1 from the fourth elastic body connector 415. For example, the fourth distance L4 may refer to the distance between the at least one eighth connection structure 415b, which is the closest connection member of the fourth elastic body connector 415, and the second mass body connector 423 of the second mass body 420. The fourth distance L4 of the second mass body 420 can be adjusted by moving the second mass body 420 along the second guide SL2 of the second elastic body 410.

The gap adjustment structure 430 may be positioned between the second elastic body 410 and the second mass body 420. For example, the gap adjustment structure 430 may be located on a lower portion of the second mass body 420 and configured to adjust a gap between the first mass body 320 and the second mass body 420.

The gap adjustment structure 430 may include a third central hole H3 at a central region. The fourth through member EM4 may sequentially pass through the second central hole H2 of the second mass body 420, the third central hole H3 of the gap adjustment structure 430, and the second guide SL2 of the second elastic body 410. The pair of fourth fastening members FM4a and FM4b may engage with end portions of the fourth through member EM4, restricting the movement of the second mass body 420, the gap adjustment structure 430, and the second elastic body 410, to secure the second mass body 420, the gap adjustment structure 430, and the second elastic body 410 in place.

The size of the gap G between the first mass body 320 and the second mass body 420 may be adjusted by changing a height of the gap adjustment structure 430 in the second horizontal direction HD2.

The first elastic body 310 may have a third thickness T3 and the second elastic body 410 may have a fourth thickness T4 equal to or less than the third thickness T3.

The first mass body 320 may have a first height HE1 from the base plate 210. For example, the first height HE1 may be a distance from the first surface 212 of the base plate 210 to the second surface 320b of the first mass body 320 along a horizontal direction. The second mass body 420 may have a second height HE2 from the base plate 210. For example, the second height HE2 may be a distance from the first surface 212 of the base plate 210 to the second surface 420b of the second mass body 420 along a horizontal direction.

The second height HE2 of the second mass body 420 may be greater than the first height HE1 of the first mass body 320. As a result, at least a portion of the second mass body 420 may be positioned above the first mass body 320. However, the present inventive concept is not limited to this configuration. For example, the second height HE2 may be less than the first height HE1. In this case, at least a portion of the second mass body 420 may be positioned below the first mass body 320.

While the figures illustrate that the gap adjustment structure 430 is provided on the lower portion of the second mass body 420, it will be appreciated that the present inventive concept is not limited thereto. For example, the gap adjustment structure 430 may be provided on the lower portion of at least one of the first mass body 320 and the second mass body 420.

A method of absorbing vibrations using the vibration absorbing apparatus 100 in accordance with example embodiments will now be described.

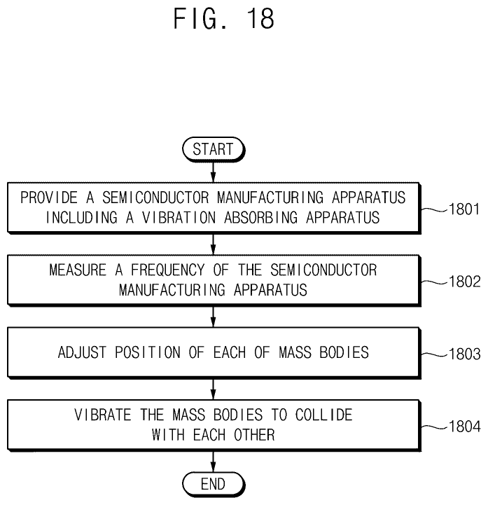

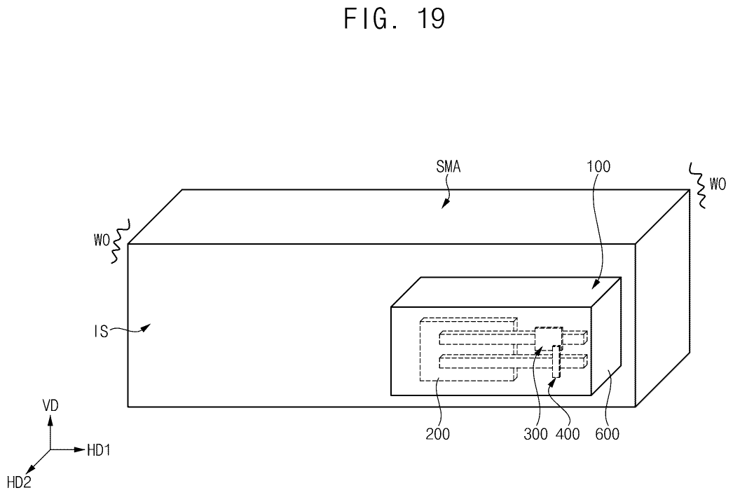

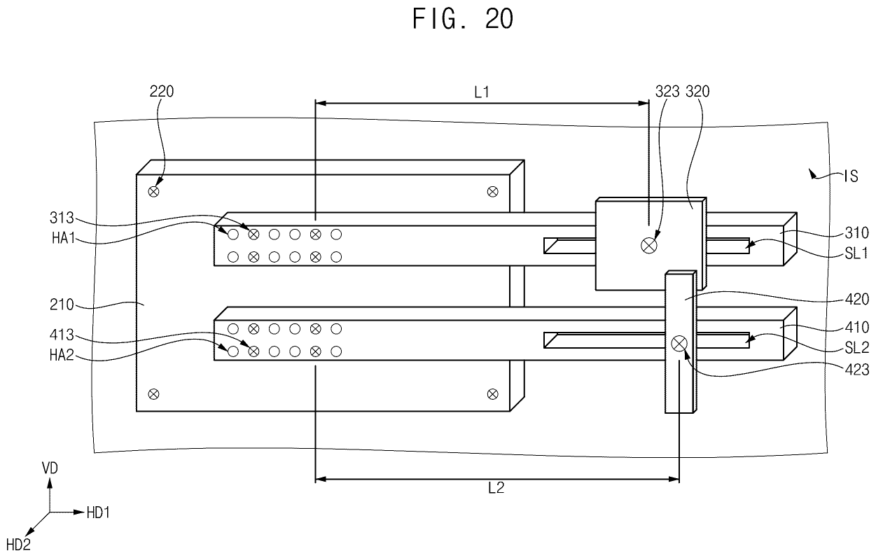

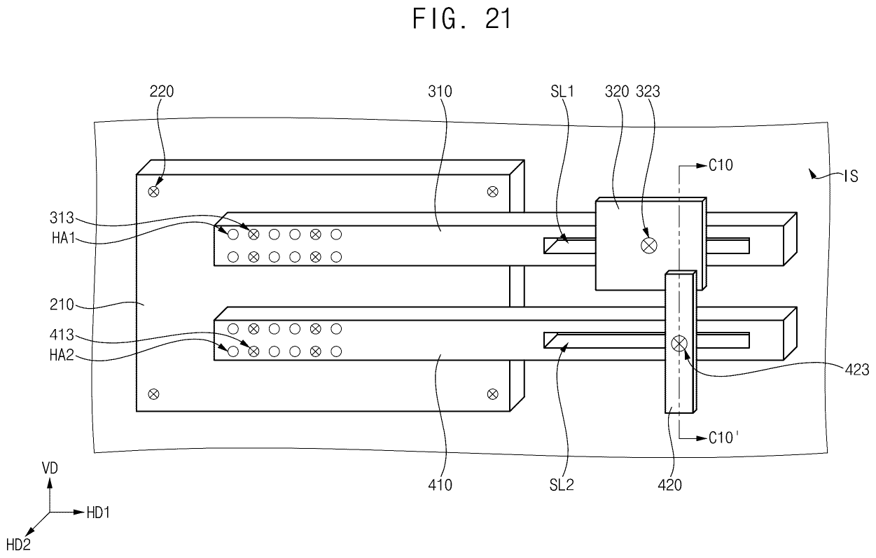

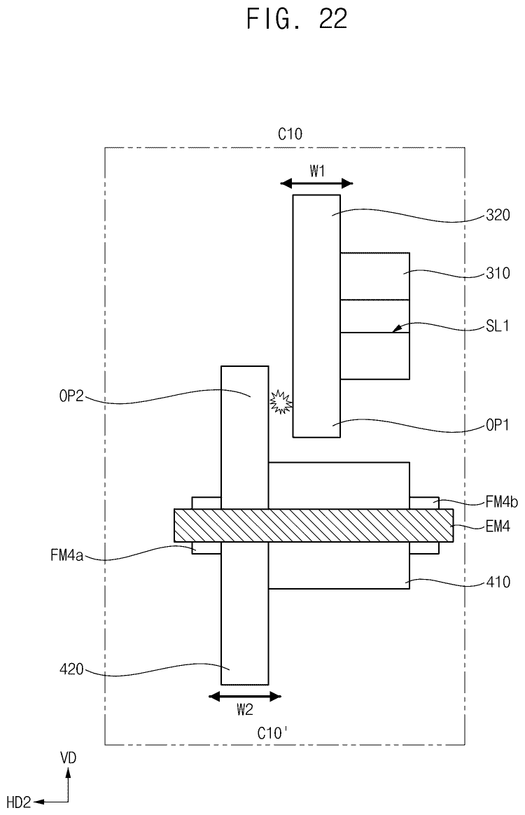

FIG. 18 is a flowchart illustrating a method of absorbing vibrations in accordance with example embodiments of the present inventive concept. FIG. 19 is a perspective view illustrating a semiconductor manufacturing apparatus vibrating at a first frequency. FIG. 20 is a perspective view illustrating the adjustment of a set frequency in a vibration absorbing apparatus by changing positions of mass bodies. FIGS. 20 to 22 are views illustrating the mass bodies in the vibration absorbing apparatus vibrating and colliding. FIG. 22 is a cross-sectional view taken along the line C10-C10′ in FIG. 21.

The vibration absorbing apparatus illustrated in FIGS. 18 to 22 is substantially identical to the vibration absorbing apparatus illustrated in FIGS. 1 to 5, so that identical components are denoted by the same reference numerals and repeated descriptions of identical components are omitted.

Referring to FIGS. 18 to 22, a semiconductor manufacturing apparatus SMA including the vibration absorbing apparatus 100 may be provided (1801). For example, the semiconductor manufacturing apparatus SMA may generate vibrations. By measuring the vibration of the semiconductor manufacturing apparatus SMA, a target frequency (W0) may be measured (1802).

By varying the first distance L1 of the first mass body 320 and the second distance L2 of the second mass body 420, the first frequency W1 of the first elastic body 310 and the second frequency W2 of the second elastic body 410 may be varied (1803).

For example, the first frequency W1 may be expressed by Equation (1) below.

$${W}_{1} = \frac{1}{2 * π} * \sqrt{\frac{3 * {E}_{1} * {I}_{1}}{{M}_{1} * {( {L}_{1} )}^{3}}} \qquad EQ ( 1 )$$

Here, E1 is the elastic modulus (Pa) of the first elastic body 310, I1 is the moment of inertia (m⁻⁴) of the first elastic body 310, M1 is the mass (kg) of the first mass body 320, L1 is the length (m) of the first distance L1, and W1 is the frequency (Hz) of the first frequency W1. For example, the second frequency W2 may be expressed by the Equation (2) below.

$${W}_{2} = \frac{1}{2 * π} * \sqrt{\frac{3 * {E}_{2} * {I}_{2}}{{M}_{2} * {( {L}_{2} )}^{3}}} \qquad EQ ( 2 )$$

Here, E2 is an elastic modulus (Pa) of the second elastic body 410, 12 is a moment of inertia (m⁻⁴) of the second elastic body 410, M2 is a mass (kg) of the second mass body 420, L2 is a length (m) of the second distance L2, and W2 is a frequency (Hz) of the second frequency W2.

For example, the first frequency W1 and the second frequency W2 may be set based on the target frequency W0 generated by the semiconductor manufacturing apparatus SMA. For example, the first distance L1 may be set such that the first frequency W1 is equal to or greater than the target frequency W0, and the second distance L2 may be set such that the second frequency W2 is equal to or less than the target frequency W0. Alternatively, the first distance L1 may be set such that the first frequency W1 is equal to or less than the target frequency W0, and the second distance L2 may be set such that the second frequency W2 is equal to or greater than the target frequency W0.

For example, the target frequency W0 may be 100 Hz or less. In this case, the first frequency W1 may be less than the target frequency W0 and greater than 0 Hz, and the second frequency W2 may be greater than the target frequency W0 and less than 100 Hz. Alternatively, the first frequency W1 may be greater than the target frequency W0 and less than 100 Hz, and the second frequency W2 may be less than the target frequency W0 and greater than 0 Hz.

For example, the vibration of the semiconductor manufacturing apparatus SMA may be transmitted to the first elastic body 310 and the second elastic body 410, causing the first elastic body 310 and the second elastic body 410 to vibrate in the second horizontal direction HD2. The first mass body 320 and the second mass body 420 may oscillate in the second horizontal direction HD2 together with the first elastic body 310 and the second elastic body 410. Thus, the first dynamic vibration absorber 300 and the second dynamic vibration absorber 400 may oscillate either in conjunction with or as a substitute for the semiconductor manufacturing apparatus SMA to reduce vibrations generated by the semiconductor manufacturing apparatus SMA.

Further, the first overlap portion OP1 of the first mass body 320 and the second overlap portion OP2 of the second mass body 420 may collide with each other (1804). The collision may generate sound, heat, or the like, which may dissipate vibration energy. Thus, by dissipating the vibration energy transmitted to the first elastic body 310 and the second elastic body 410, the vibration of the semiconductor manufacturing apparatus SMA may be reduced.

In this case, greater collisions result in increased dissipation of vibration energy. For example, larger vibrations cause more significant collisions between the first mass body 320 and the second mass body 420, thereby dissipating more vibration energy. Thus, these collisions may create mechanical feedback that gradually reduces the vibration.

The foregoing examples are illustrative of the disclosed embodiments and should not be considered limiting. Although a few example embodiments have been described, those skilled in the art will recognize that various modifications can be made without departing from the novel teachings and advantages of the present inventive concept. Therefore, all such modifications are intended to be included within the scope of example embodiments as set forth in the claims.

1. A vibration absorbing apparatus for semiconductor manufacturing apparatus, comprising:
a base plate configured to be secured to a semiconductor manufacturing apparatus;
a first vibration absorber including a first elastic body fastened to the base plate and a first mass body fastened to the first elastic body; and
a second vibration absorber including a second elastic body fastened to the base plate and a second mass body fastened to the second elastic body, wherein the second elastic body is adjacent to the first elastic body,
wherein the first mass body and the second mass body are configured to reduce vibration at specific frequencies transmitted to the base plate by colliding with each other.

2. The vibration absorbing apparatus of claim 1, wherein the first elastic body includes a first beam structure that has a first fixed end portion fastened to the base plate and a first free end portion extending from the first fixed end portion along a first horizontal direction, and
wherein the second elastic body includes a second beam structure that has a second fixed end portion fastened to the base plate and a second free end portion extending from the second fixed end portion along the first horizontal direction.

3. The vibration absorbing apparatus of claim 2, wherein the first beam structure includes a first guide extending in the first horizontal direction and located at the first free end portion, with the first mass body positioned along the first guide,
wherein the second beam structure includes a second guide extending in the first horizontal direction and located at the second free end portion, with the second mass body positioned along the second guide.

4. The vibration absorbing apparatus of claim 1,
wherein the first mass body is located at a first height from a first surface of the base plate, and the second mass body is located at a second height from the first surface of the base plate, wherein the second height is greater than the first height,
wherein a gap is provided between a second surface of the first mass body and a third surface of the second mass body, the second surface and the third surface facing each other.

5. The vibration absorbing apparatus of claim 4, further comprising:
an impact portion disposed in the gap and configured to collide with at least one of the first mass body and the second mass body.

6. The vibration absorbing apparatus of claim 5, wherein the impact portion includes a plurality of springs disposed on an end portion of the at least one of the first mass body and the second mass body.

7. The vibration absorbing apparatus of claim 5, wherein the impact portion includes,
a box portion disposed on an end portion of the at least one of the first mass body and the second mass body and having a sealed space; and
a plurality of particle structures within the sealed space and configured to collide with each other.

8. The vibration absorbing apparatus of claim 5,
wherein an extending portion is disposed on an end portion of the at least one of the first mass body and the second mass body, such that the extending portion penetrates the at least one of the first mass body and the second mass body; and
an impact member disposed on an end portion of the extending portion.

9. The vibration absorbing apparatus of claim 1,
wherein the first elastic body and the second elastic body each extend in a first direction, and
wherein the first mass body and the second mass body are partially overlapped with each other in a second direction different from the first direction.

10. The vibration absorbing apparatus of claim 9, wherein a first portion of the first mass body overlapped with the second mass body and a second portion of the second mass body overlapped with the first mass body vibrate in the second direction and collide with each other.

11. A vibration absorbing apparatus for semiconductor manufacturing apparatus, comprising:
a base plate configured to be secured to a semiconductor manufacturing apparatus;
a first beam structure including a first fixed end portion secured to the base plate and a first free end portion extending from the first fixed end portion;
a second beam structure adjacent to the first beam structure and including a second fixed end portion secured to the base plate and a second free end portion extending from the second fixed end portion;
a first mass body fastened to the first free end portion of the first beam structure; and
a second mass body fastened to the second free end portion of the second beam structure,
wherein the first mass body and the second mass body partially overlap each other, and the first mass body and the second mass body are configured to reduce vibrations at frequencies applied to the base plate by colliding with each other.

12. The vibration absorbing apparatus of claim 11, wherein the first beam structure includes a first guide extending in a first horizontal direction and located at the first free end portion, with the first mass body positioned along the first guide,
wherein the second beam structure includes a second guide extending in the first horizontal direction and located at the second free end portion, with the second mass body positioned along the second guide.

13. The vibration absorbing apparatus of claim 12, wherein the first mass body has a first distance in the first horizontal direction from the first fixed end portion, and the first distance is adjustable along the first guide to tune a first frequency of the first beam structure, and
wherein the second mass body has a second distance in the first horizontal direction from the second fixed end portion, and the second distance is adjustable along the second guide to tune a second frequency of the second beam structure.

14. The vibration absorbing apparatus of claim 13, wherein a vibration of the semiconductor manufacturing apparatus has a third frequency, and
wherein the first frequency is equal to or less than the third frequency, and the second frequency is equal to or greater than the third frequency.

15. The vibration absorbing apparatus of claim 13, wherein a vibration of the semiconductor manufacturing apparatus has a third frequency, and
wherein the first frequency is equal to or greater than the third frequency, and the second frequency is equal to or less than the third frequency.

16. The vibration absorbing apparatus of claim 11, wherein a gap is provided between a first surface of the first mass body and a second surface of the second mass body, the first surface and the second surface facing each other.

17. The vibration absorbing apparatus of claim 16, further comprising:
an impact portion disposed in the gap and configured to collide with at least one of the first mass body and the second mass body.

18. (canceled)

19. The vibration absorbing apparatus of claim 17, wherein the impact portion includes,
a box portion disposed on an end portion of the at least one of the first mass body and the second mass body and having a sealed space; and
a plurality of particle structures within the sealed space and configured to collide with each other.

20. The vibration absorbing apparatus of claim 17, wherein the impact portion includes,
an extending portion disposed on an end portion of the at least one of the first mass body and the second mass body, such that the extending portion penetrates the at least one of the first mass body and the second mass body; and
an impact member disposed on an end portion of the extending portion.

21. A vibration absorbing apparatus for semiconductor manufacturing apparatus, comprising:
a base plate configured to be secured to a semiconductor manufacturing apparatus, the base plate having a first surface and a second surface facing each other;
a first beam structure including a first fixed end portion secured to the first surface of the base plate and a first free end portion extending from the first fixed end portion and having a first slit formed along an extending direction;
a second beam structure spaced apart from the first beam structure and including a second fixed end portion secured to the first surface of the base plate and a second free end portion extending from the second fixed end portion and having a second slit formed along the extending direction;
a first mass body positioned along the first slit; and
a second mass body positioned along the second slit and extending toward the first mass body such that the second mass body is at least partially overlapped with the first mass body,
wherein the first mass body and the second mass body are configured to reduce vibrations at certain frequencies applied to the base plate by colliding with each other.

22-30. (canceled)
